(19) United States
(12) Patent Application Publication
(10) Pub. No.: US 2011/0167197 A1
(43) Pub. Date: Jul. 7, 2011

(54) Nonvolatile Storage with Disparate Memory Types

(76) Inventor: Mark Leinwander, Folsom, CA (US)

(21) Appl. No.: 12/652,666

(22) Filed: Jan. 5, 2010

(51) Int. Cl. G06F 12/00; G06F 12/02; G11C 11/00

(52) U.S. Cl. 711/103; 365/163; 711/E12.001; 711/E12.008

(57) ABSTRACT

Disparate nonvolatile memory types are included in a system. Writes are performed in a first type of nonvolatile memory when the size of the write is below a threshold, and are performed in a second type of nonvolatile memory when the size of the write is above the threshold. The threshold may be a number of sectors. The disparate memory types may include FLASH memory and phase change memory (PCM).

### FIELD

The present invention relates generally to data storage in memory devices, and more specifically to data storage in nonvolatile memory.

### BACKGROUND

FLASH memory is a type of nonvolatile memory. It is “nonvolatile” because it retains its memory contents even when power is lost. Individual locations within FLASH memory typically cannot be overwritten. Instead, entire blocks of data within FLASH memory devices must be erased before individual locations within the block can be written. This is referred to herein as the “block erase characteristic” of FLASH memory.

FLASH memory is in widespread use in systems that benefit from nonvolatile memory. Examples include, but are not limited to, cell phones, cameras, media players, and the like. FLASH memory is also in widespread use for disk emulation (also referred to as “solid state disks”). In these systems, read and write commands are presented to the solid state disks as disk operations (e.g., reading of disk sectors and writing of disk sectors). Because of the block erase characteristic, FLASH memory may be inefficient when subjected to many small write operations.

### BRIEF DESCRIPTION OF THE DRAWINGS

Embodiments of the invention are illustrated by way of example and not limitation in the figures of the accompanying drawings, in which:

FIG. 1 shows an electronic system in accordance with various embodiments of the invention;

FIG. 2 shows a flow diagram in accordance with various embodiments of the present invention;

FIG. 3 shows the format of an example write command; and

FIGS. 4 and 5 show memory systems in accordance with various embodiments of the present invention.

### DESCRIPTION OF EMBODIMENTS

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein in connection with one embodiment may be implemented within other embodiments without departing from the scope of the invention. In addition, it is to be understood that the location or arrangement of individual elements within each disclosed embodiment may be modified without departing from the scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Some portions of the detailed description that follows are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Unless specifically stated otherwise, as apparent from the following discussions, it is appreciated that throughout the specification discussions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

Embodiments of the present invention may include apparatuses for performing the operations herein. An apparatus may be specially constructed for the desired purposes, or it may comprise a general purpose computing device selectively activated or reconfigured by a program stored in the device. Such a program may be stored on a storage medium or other computer-readable medium, such as, but not limited to, any type of disk including floppy disks, optical disks, compact disc read only memories (CD-ROMs), magnetic-optical disks, read-only memories (ROMs), random access memories (RAMs), nonvolatile memories such as electrically programmable read-only memories (EPROMs), electrically erasable and programmable read only memories (EEPROMs), or FLASH memories, or any other type of media suitable for storing electronic instructions, and capable of being coupled to a system bus for a computing device.

Use of the terms “coupled” and “connected”, along with their derivatives, may be used. It should be understood that these terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements cooperate or interact with each other (e.g., as in a cause and effect relationship).

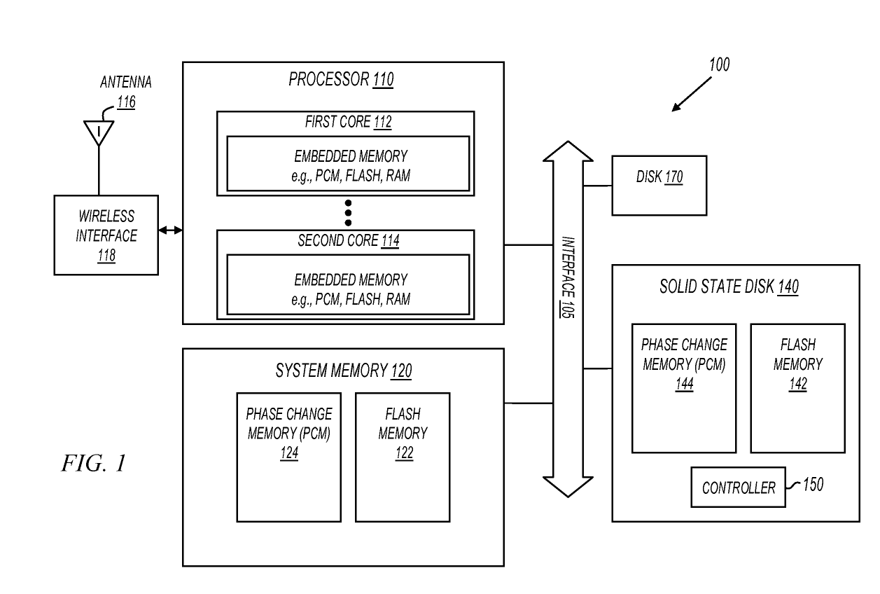

FIG. 1 shows a system 100 in accordance with various embodiments of the present invention. System 100 may be any type of system with memory. For example, system 100 may be a computer or a mobile phone with nonvolatile memory. Also for example, system 100 may be a global positioning system (GPS) receiver or a portable media player with nonvolatile memory. System 100 may be any type of device without departing from the scope of the present invention.

In some embodiments, system 100 has a wireless interface 118. Wireless interface 118 is coupled to antenna 116 to allow system 100 to communicate with other over-the-air communication devices. As such, system 100 may operate as a cellular device or a device that operates in wireless networks such as, for example, Wireless Local Area Networks (WLANs), WiMax and Mobile WiMax based systems, Wideband Code Division Multiple Access (WCDMA), and Global System for Mobile Communications (GSM) networks, any of which may or may not operate in accordance with one or more standards. The various embodiments of the invention are not limited to operate in the above network types; this is simply a list of examples. It should be understood that the scope of the present invention is not limited by the types of, the number of, or the frequency of the communication protocols that may be used by system 100. Embodiments are not, however, limited to wireless communication embodiments. Other non-wireless applications can use the various embodiments of the invention.

In some embodiments, wireless interface 118 may include one or more stand-alone Radio Frequency (RF) discrete or integrated analog circuits, and in other embodiments, wireless interface 118 may be embedded within an integrated circuit that includes other components. For example, in some embodiments, wireless interface 118 may be included on a common integrated circuit with processor 110.

Processor 110 includes at least one core 112, 114, and each core may include memory. For example, first core 112 may include volatile or nonvolatile memory such as phase change memory (PCM), FLASH, or RAM. Each core may include any combination of different types of memory without departing from the scope of the present invention. Processor 110 may execute instructions from any suitable memory within system 100. For example, any memory within a processor core, any of the memory devices within system memory 120, or any of the memory within solid state disk (SSD) 140, may be considered a computer-readable medium that has instructions stored that when accessed cause processor 110 to perform embodiments of the invention.

Processor 110 is shown coupled to interface 105. Interface 105 provides communication between processor 110 and the various other devices coupled to interface 105. For example, processor 110 may communicate with memory devices in system memory 120, solid state disk (SSD) 140, as well as disk 170. Interface 105 can include serial and/or parallel buses to share information along with control signal lines to be used to provide handshaking between processor 110 and the various other devices coupled to interface 105.

System 100 may or may not include disk 170. For example, some mobile phone embodiments do not include disk 170. Also for example, some computer embodiments include disk 170.

Solid state disk (SSD) 140 includes FLASH memory 142, phase change memory (PCM) 144, and controller 150. FLASH memory stores information by storing charge on a floating gate in a Metal Oxide Semiconductor (MOS) transistor. The stored charge alters the threshold voltage of the transistor, and the difference in threshold voltage is “read” to determine whether the stored information is a “0” or a “1”. In some embodiments varying amounts of charge are stored on the floating gate to represent more than one bit of information per memory cell. This is sometimes referred to as Multi-Level Cell (MLC) FLASH. FLASH memory 142 may be any type of FLASH memory, including NOR FLASH memory, NAND single level cell (SLC) memory, or NAND multi-level cell (MLC) memory.

Solid state disk 140 also includes phase change memory (PCM) 144. Phase change memories are memories that store information based on modifiable material properties, such as whether a material is in a crystalline or amorphous state (phase). For example, in some embodiments, phase change memories include alloys of elements of group 16 of the periodic table, such as Te or Se, that are referred to as chalcogenides or chalcogenic materials. Chalcogenides may be used advantageously in phase change memory cells to provide data retention and remain stable even after the power is removed from the nonvolatile memory. Taking the phase change material as Ge₂Sb₂Te₅ for example, two phases or more are exhibited having distinct electrical characteristics useful for memory storage. Phase change memory may be referred to as a Phase Change Memory (PCM), Phase-Change Random Access Memory (PRAM or PCRAM), Ovonic Unified Memory (OUM), Chalcogenide Random Access Memory (C-RAM), or other suitable names. PCM can be directly overwritten at a bit-level, and is not subject to the block erasure constraints that FLASH memory is subject to.

Controller 150 may be any type of controller, including a microcontroller, a microprocessor, a state machine, or the like. In various embodiments, controller 150 receives read and write commands and performs reads from, and writes to, both FLASH memory 142 and PCM 144. Sector or block storage devices such as solid state drives generally receive data transfer commands in four basic forms: Sector Read, Sector Write, Multi-Sector Read, and Multi-Sector Write. The underlying media is abstracted to look like sectors or blocks, keeping the media management on the storage device and allowing the host system just to deal with a linear list of sectors or Logical Block Addresses (LBAs). Therefore, the host system's file systems and drivers are not able to determine if a section of the address space is more reliable or has different performance characteristics without partitioning the drive, which separates the address spaces.

To take advantage of PCM features in a storage system such as a solid state drive with FLASH memory, various embodiments of the invention interpret data transfer commands to control the parsing of the sectors to allow for placement into disparate nonvolatile memory types, such as PCM and FLASH. Sector writes are generally in one of two forms: multi-sector write commands and single sector write commands. The single sector write command only transfers one sector of data at an indicated LBA (Logical Block Address), as specified in the command header. The multi-sector write command transfers multiple sectors as indicated in a sector count field in the command header. In some embodiments, single sector writes are performed in PCM and multi-sector writes that are smaller than a particular threshold are also performed in PCM, whereas larger writes are performed in FLASH memory.

Although SSD 140 is shown with FLASH memory and PCM, this is not a limitation of the present invention. For example, in some embodiments, other disparate memory types are included in SSD 140. Examples include Magnetic Random Access Memory (MRAM), and Ferroelectric Random Access Memory (FRAM).

Magnetic Random Access Memory (MRAM) have magnetic storage elements formed from two ferromagnetic plates located at an intersection of a row and column line and selected by a Magnetic Tunnel Junction (MTJ) device. Current imparted to the row line in one direction causes a magnetic field operative on the MRAM cell biasing the MRAM cell toward a binary state. Due to a magnetic tunnel effect, the electrical resistance of the memory cell changes based on the orientation of the fields in the two plates.

Ferro-electric Random Access Memory (FRAM) have memory cells that may include one transistor and one capacitor. The capacitor includes ferroelectric material and a bi-stable atom in the ferroelectric material is shifted to form two stable polarization states. Memory cell data may be written by positively or negatively orienting the dipoles of the ferroelectric material via an applied polarizing voltage. Data may be read by detecting the voltage of the bit line (BL) connected with the memory cell. Current feed circuits supply electric currents to the bit lines for a predetermined period from a start of a read operation, and read control circuitry senses the direction of the electric polarization as either a high or a low logic state. Each orientation is stable and remains in place even after the electric field is removed, preserving the data within the memory without periodic refresh.

Memory devices within SSD 140 may be packaged in any manner. For example, in some embodiments, FLASH memory 142 and PCM 144 may be combined in a stacking process to reduce the footprint on a board, packaged separately, or placed in a multi-chip package with the memory component placed on top of the controller.

System memory 120 may include any type of memory. For example, as shown in FIG. 1, system memory 120 may include FLASH memory 122 and PCM 124. In some embodiments, small write operations are performed using PCM 124 and larger writes are performed using FLASH 124. By using disparate memory types based on the size of the write, the benefits of PCM can be incorporated into a FLASH-based memory system. For example, PCM can be overwritten bit by bit, whereas FLASH memory is subject to block erasure constraints.

Memory devices within system memory 120 may be packaged in any manner. For example, in some embodiments, FLASH memory 122 and PCM 124 may be combined in a stacking process to reduce the footprint on a board, packaged separately, or placed in a multi-chip package with the memory component placed on top of the processor.

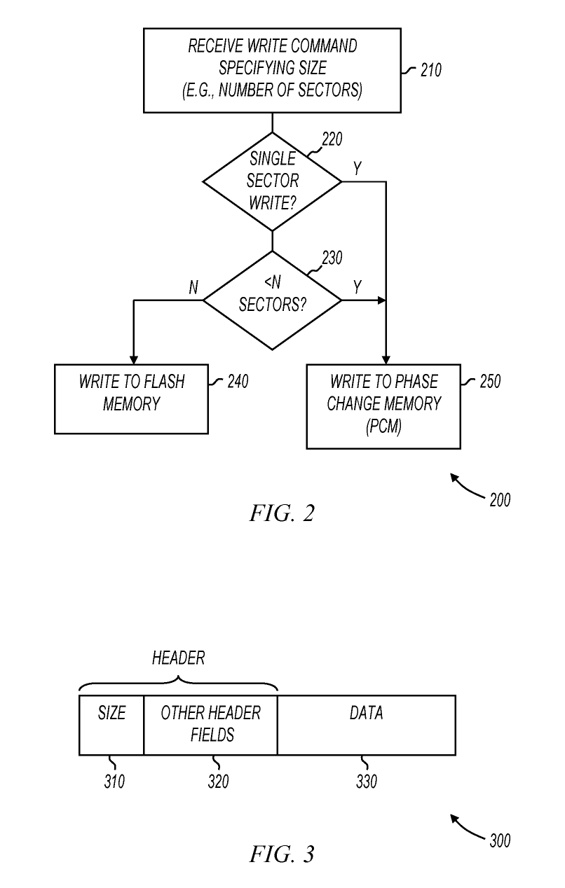

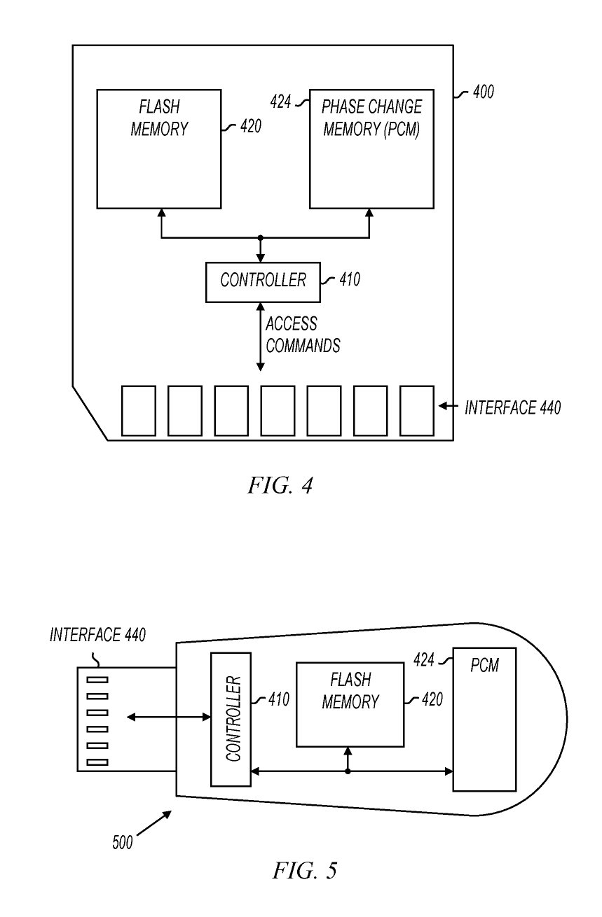

FIG. 2 shows a flow diagram in accordance with various embodiments of the invention. In some embodiments, method 200, or portions thereof, is performed by a processor, controller, or state machine coupled to or within a memory device or system. For example, method 200 may be performed by processor 110 (FIG. 1), controller 150 (FIG. 1), or controller 410 (FIGS. 4, 5). The various actions in method 200 may be performed in the order presented, or may be performed in a different order. Further, in some embodiments, some actions listed in FIG. 2 are omitted from method 200.

Method 200 is shown beginning at block 210 in which a write command is received. The write command specifies a size, which may be specified as a number of sectors to be written, a number of bytes to be written, or any other quantity. The write command also includes data to be written. An example of a write command is shown in FIG. 3. Write command 300 includes data 330 and a header. The header includes a size field 310 and other fields 320. Other fields 320 may include any type of additional field, including for example, an address field, a command field that specifies a single sector write or multi-sector write, and the like. In some embodiments, the write command is formed as a data transfer command, and is received at a solid state disk (SSD) such as SSD 140 (FIG. 1).

Method 200 checks the size of the data to be written, and writes to a first type of nonvolatile memory when the size is below a threshold, and writes to a second type of nonvolatile memory when the size is above the threshold. For example, at 220, method 200 determines if the write command is for a single sector write. When the command is for a single sector write, then the write is performed in PCM at 250. In this example, the threshold is one sector. When the command is for a single sector write, the write is performed in the first type of nonvolatile memory (PCM).

At 230, the write command is a multi-sector write. The number of sectors is compared to a threshold, “N”. If the number of sectors to be written is less than the threshold, then method 200 writes to PCM at 250, and if the number of sectors is greater than or equal to the threshold “N”, then method 200 writes to FLASH memory at 240.

When method 200 is executed by an SSD or a controller within an SSD, the benefits of PCM can be included in a FLASH-based SSD without any changes necessary to the host system. For example, when data is written to a file system, many small writes may accompany a large write. The small writes may store metadata describing the actual data payload. Especially in the case of small data objects such as contact lists update or calendar updates, the ratio of small writes to large writes may be extremely high. PCM handles small writes more efficiently than FLASH memory because PCM is not constrained by the block erase characteristics of FLASH memory.

FIG. 4 shows a memory system in accordance with various embodiments of the present invention. Memory system 400 includes FLASH memory 420, PCM 424, controller 410, and interface 440. Memory system 400 is shown having a Secure Digital (SD) form factor, although this is not a limitation of the present invention. For example, in some embodiments, memory system 400 may be a card compatible with a bus within a personal computer. Also for example, in some embodiments, memory system 400 may be a micro-SD card, a memory stick, a MultiMediaCard (MMC), embedded MMC (eMMC), or any other type of card.

In operation, controller 410 receives access commands from interface 440. The access commands may take any form. For example, if memory system 400 operates as a solid state disk, the access commands may be disk access commands. In other embodiments, the access commands may be other than disk access commands. The access commands include read and write commands. Example write commands include single sector write commands and multi-sector write commands. Controller 410 interprets the write commands and determines based on the size of the commands whether to write data to FLASH memory 420 or PCM 424.

The various components shown in FIG. 4 may be packaged in any manner. For example, in some embodiments, controller 410 and FLASH memory 420 are fabricated on the same semiconductor substrate. Further, in some embodiments, PCM 424 is fabricated on a common substrate with FLASH memory 420 and controller 410. Further in some embodiments, controller 410 and FLASH memory 420 are fabricated on one substrate and PCM 424 is fabricated on a second substrate. In some embodiments, the two substrates are stacked prior to packaging in memory system 400.

FIG. 5 shows a memory system in accordance with various embodiments of the present invention. Memory system 500 includes FLASH memory 420, PCM 424, controller 410, and interface 440, all of which are described above with reference to FIG. 4. Memory system 500 is shown having a universal serial bus (USB) device form factor, although this is not a limitation of the present invention. Memory system 500 may take any form factor without departing from the scope of the present invention.

Memory systems 400 (FIG. 4) and 500 (FIG. 5) are but examples of apparatuses that include disparate types of nonvolatile memory such as FLASH memory and PCM. The apparatuses according to embodiments of the invention are not limited to memory cards or USB devices, but instead may take any form. They may be embedded in devices such as cameras, phones, media players, GPS devices, or any other type of device. They may also take on any stand-alone form factor, including solid state disks, memory cards and USB devices.

Although the present invention has been described in conjunction with certain embodiments, it is to be understood that modifications and variations may be resorted to without departing from the scope of the invention as those skilled in the art readily understand. Such modifications and variations are considered to be within the scope of the invention and the appended claims.

What is claimed is:

1. A method comprising:
receiving a write command, the write command including data and a size;
when the size is below a threshold, writing the data to a first type of nonvolatile memory; and
when the size is above the threshold, writing the data to a second type of nonvolatile memory.

2. The method of claim 1 wherein receiving a write command comprises receiving a command to write to a disk.

3. The method of claim 1 wherein writing the data to a first type of nonvolatile memory comprises writing the data to phase change memory (PCM).

4. The method of claim 3 wherein writing the data to a second type of nonvolatile memory comprises writing the data to FLASH memory.

5. The method of claim 4 wherein writing the data to FLASH memory comprises writing the data to NAND FLASH memory.

6. The method of claim 4 wherein the method is performed by a controller packaged together with the FLASH memory and the PCM.

7. The method of claim 1 wherein the size comprises a number of sectors.

8. The method of claim 1 wherein the size comprises a number of bytes.

9. The method of claim 1 wherein receiving a write command comprises receiving a command to write to a solid state disk (SSD).

10. A machine-readable medium having instructions stored thereon that when accessed result in a machine performing:
receiving a command to write to a disk drive, the command including data and a size;
when the size is below a threshold, writing the data to a first type of nonvolatile memory; and
when the size is above the threshold, writing the data to a second type of nonvolatile memory.

11. The machine-readable medium of claim 10 wherein writing the data to a first type of nonvolatile memory comprises writing the data to phase change memory (PCM).

12. The machine-readable medium of claim 11 wherein writing the data to a second type of nonvolatile memory comprises writing the data to FLASH memory.

13. The machine-readable medium of claim 10 wherein the size comprises a number of sectors.

14. The machine-readable medium of claim 10 wherein receiving a write command comprises receiving a command to write to a solid state disk (SSD).

15. An apparatus comprising:
phase change memory (PCM);
FLASH memory; and
a controller to write to the PCM or the FLASH memory based on a commanded write size.

16. The apparatus of claim 15 wherein the FLASH memory comprises NAND FLASH memory.

17. The apparatus of claim 15 wherein the commanded write size comprises a number of sectors.

18. The apparatus of claim 15 wherein the apparatus comprises a solid state disk.

19. The apparatus of claim 15 wherein the apparatus comprises a memory card.

20. The apparatus of claim 15 wherein the apparatus comprises a universal serial bus (USB) drive.
